(19) United States
(12) Patent Application Publication
(10) Pub. No.: US 2006/0046356 A1
(43) Pub. Date: Mar. 2, 2006

(54) Method for forming a circuit package having a thin substrate

(75) Inventors: Gregory Eric Howard, Dallas, TX (US); Leland Swanson, McKinney, TX (US)

Correspondence Address: TEXAS INSTRUMENTS INCORPORATED, P O BOX 655474, M/S 3999, DALLAS, TX, 75265, US

(73) Assignee: Texas Instruments Incorporated

(21) Appl. No.: 10/931,104

(22) Filed: Aug. 31, 2004

(51) Int. Cl. H01L 21/84; H01L 21/302

(52) U.S. Cl. 438/149; 438/753

(57) ABSTRACT

According to one embodiment, a method of manufacturing a semiconductor device is provided. The method comprises forming a silicon-on-insulator (SOI) wafer. The SOI wafer has a carrier silicon layer, an oxide layer disposed outwardly from the carrier silicon layer, and a silicon layer disposed outwardly from the oxide layer. The method also includes forming at least one feature at least partially in the silicon layer. The method also includes separating the carrier silicon layer from the silicon layer by chemically removing the oxide layer.

### TECHNICAL FIELD OF THE INVENTION

This invention relates generally to electronics and more particularly to a method for forming a circuit package having a thin substrate.

### OVERVIEW

A circuit in an electronic device may be implemented as a package. An example of a package is a die. With the drive for miniaturization of electronic devices, a die having a thinner profile may be desirable.

### SUMMARY OF EXAMPLE EMBODIMENTS

According to one embodiment, a method for manufacturing a semiconductor device is provided. The method includes forming a silicon-on-insulator (SOI) wafer. The SOI wafer has a carrier silicon layer, an oxide layer disposed outwardly from the carrier silicon layer, and a silicon layer disposed outwardly from the oxide layer. The method also includes forming at least one feature at least partially in the silicon layer. The method also includes separating the carrier silicon layer from the silicon layer by chemically removing the oxide layer.

In another embodiment, a method of manufacturing a semiconductor device is provided. The method includes forming a silicon layer having a thickness of approximately 10 microns or less disposed outwardly from a platform. The method also includes forming at least one feature at least partially in the silicon layer. The feature does not reach the platform. The method also includes removing the platform after forming the feature.

Various embodiments may realize some, none, or all of the following advantages. For example, according to one embodiment, the size of a circuit package may be reduced by forming features in a thin silicon layer of a silicon-on-insulator (SOI) wafer and removing the carrier wafer of the SOI wafer. In another embodiment, silicon waste is reduced by reusing the removed carrier wafer for other semiconductor applications.

Other advantages may be readily ascertainable by those skilled in the art.

### BRIEF DESCRIPTION OF THE DRAWINGS

Reference is now made to the following description taken in conjunction with the accompanying drawings, wherein like reference numbers represent like parts, in which:

FIGS. 1 through 7 are a series of schematic cross-sectional diagrams illustrating one embodiment of a semiconductor device constructed according to one embodiment of the present invention.

### DETAILED DESCRIPTION OF EXAMPLE EMBODIMENTS

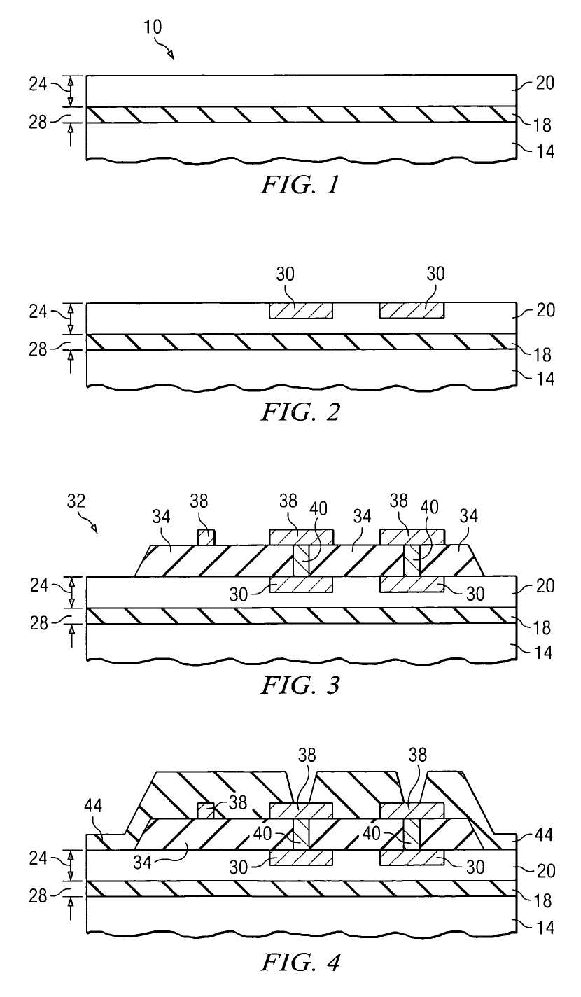

According to one embodiment, the size of a semiconductor device is reduced by forming a circuit using an epitaxial layer of a silicon-on-insulator (SOI) wafer, and removing the carrier wafer from the SOI wafer. Example methods of reducing the size of a circuit package are described below in conjunction with FIGS. 1 through 7, which are a series of schematic cross-sectional diagrams illustrating one embodiment of a semi-conductor device 80 constructed according to one embodiment of the present invention. FIGS. 1 through 7 are described jointly. Throughout this description, the terms “outwardly” and “inwardly” are used to describe relative positions of structures. These terms are not intended to require a particular orientation or direction of any device. In this document, “coupled” or “couple” refers to any direct or indirect connection between two or more objects.

Referring to FIG. 1, a silicon-on-insulator (SOI) wafer 10 comprises a silicon carrier wafer 14, an oxide layer 18 disposed outwardly from carrier wafer 14, and a silicon layer 20 disposed outwardly from oxide layer 18. In one embodiment, silicon layer 20 is an epitaxial (EPI) layer 20 of SOI wafer 10 and oxide layer 18 is a buried oxide layer (BOx) of SOI wafer 10. In one example embodiment, oxide layer 18 has a thickness 28 of approximately two microns or less, and silicon layer 20 has a thickness 24 in one of the following ranges; equal to or less than 20 microns, equal to or less than 10 microns, equal to or less than five microns, equal to or less than one micron, and equal to or greater than one micron. Other layer dimensions could be used depending on the particular application. SOI wafer 10 may be formed using any suitable SOI process, such as a hydrogen ion implant method.

Referring to FIG. 2, in one embodiment, one or more features 30, such as a trench 30 or a via, may be formed at least partially in silicon layer 20. In some embodiments, a complete circuit may be formed in silicon layer 20. In one embodiment, the depth of feature 30 does not exceed 50% of thickness 24, and feature does not penetrate through silicon layer 20 to reach oxide layer 18. Referring to both FIGS. 1 and 2, thickness 24 of silicon layer 20 may be varied to accommodate any features to be formed in silicon layer 20 so that the features do not penetrate through silicon layer 20 to reach oxide layer 18.

Referring to FIG. 3, in one embodiment, an oxide layer 34 is formed outwardly from silicon layer 20. Oxide layer 34 may include features 40, such as vias 40. Contacts 38, formed from metal for example, are formed outwardly from oxide layer 34 and may be positioned over via 40. Via 40 may be filled with an at least substantially conductive material to make an electrical connection between metal 38 and trench 30. In this particular example, vias 40 are filled with copper. Trenches 30, vias 40, and metal contacts 38 are jointly referred to as a circuit 32. Trenches 30, vias 40, and contacts 38 are shown in FIGS. 2 and 3 as one example of a circuit that may be formed using silicon layer 20. However, any suitable component and/or combination of components may be used to form a circuit using silicon layer 20. Using silicon layer 20 of SOI wafer 10 to form a circuit is advantageous in some embodiments because the thickness of the resulting die can be reduced.

Referring to FIG. 4, after a suitable circuit, such as circuit 32, is formed using silicon layer 20 as shown in FIGS. 2 through 3, a protective layer 44 is formed outwardly from oxide layer 34, in one embodiment. Protective layer 44 may be formed from a passivation oxide layer using a chemically stable material, such as amorphous hydrogenated silicon carbide (a-Sic:H) or amorphous hydrogenated boron carbide (a-B₄C:H). In one embodiment, protective layer 44 substantially covers the entire oxide layer 34. As shown in FIG. 4, in an example where oxide layer 34 has a smaller footprint than silicon layer 20, protective layer 44 may extend beyond the footprint of oxide layer 34 and extend out to the edge of silicon layer 20. This is advantageous in certain embodiments where oxide layer 18 is chemically removed from SOI wafer 10 because protective layer 44 may prevent the chemical used to remove oxide layer 18 from also removing oxide layer 34. In some embodiments, protective layer 44 may be omitted.

Referring to FIG. 5, a wafer handler 48 secures protective layer 44 using a suitable method, such as vacuum suction. In some embodiments, wafer handler 48 is operable to rotate around an axis, as shown in FIG. 5. Oxide layer 18 is exposed to a chemical 54 suitable for removing oxide layer 18, thereby separating carrier wafer 14 from silicon layer 20. An example of chemical 54 includes, but is not limited to, a mixture of hydrofluoric (HF) acid and a suitable surfactant, such as alcohol. In some embodiments, chemical 54 includes a HF acid concentration level that is equal to or greater than five percent, or equal to or less than 49 percent. Although certain HF acid concentration levels are provided above, any concentration of HF acid concentration level operable to remove oxide layer 18 without significantly damaging the desired remaining structure may be used. Although alcohol is described as an example surfactant, any suitable surfactant for reducing the surface tension of liquid, such as HF acid, may be used as a surfactant in chemical 54. In one embodiment, the use of a surfactant in chemical 54 is advantageous because the reduction of the surface tension of chemical 54, such as hydrofluoric acid, facilitates the insertion of chemical 54 between silicon layer 20 and carrier wafer 14 to remove oxide layer 18.

Various methods may be used to deliver chemical 54 to oxide layer 18 and remove oxide layer 18. For example, as shown in FIG. 5, a nozzle 50 may be used to spray chemical 54 on oxide layer 18 while wafer handler 48 is rotating. The rotation of wafer handler 48 allows dissolved portions of oxide layer 18 to be removed via centrifugal force generated by the rotation of wafer handler 48. Although one example of exposing oxide layer 18 to chemical 54 is described in conjunction with FIG. 5, other suitable methods of exposure may be used to dissolve oxide layer 18. For example, oxide layer 18 may be bathed in a suitable chemical to dissolve oxide layer 18 without rotating wafer handler 48. Although a chemical removal of oxide layer 18 is described above, other methods of oxide removal may be used to remove oxide layer 18, thereby separating carrier wafer 14 from silicon layer 20.

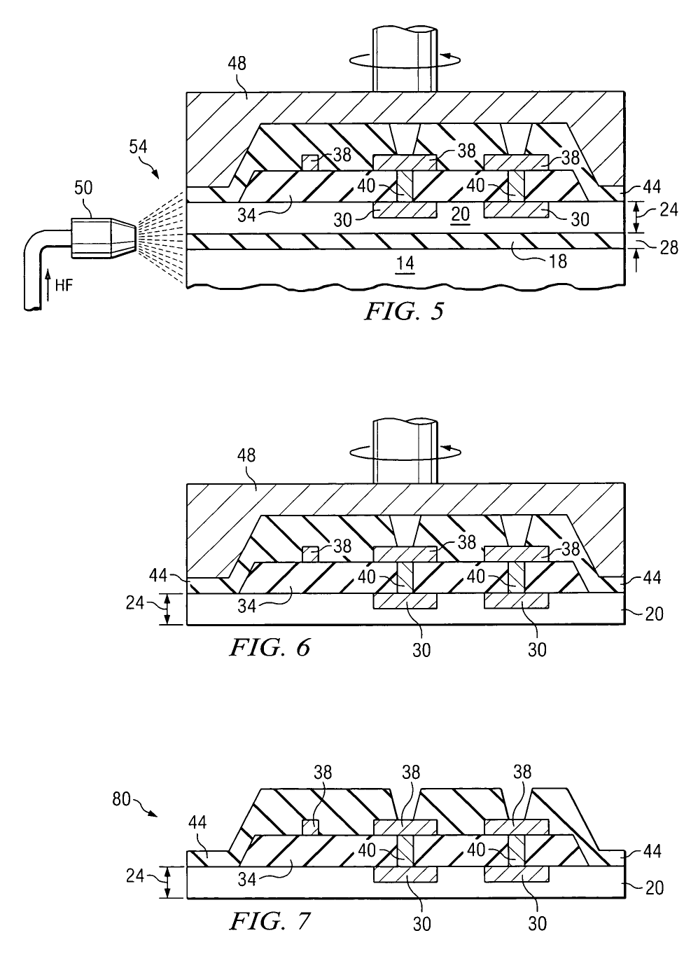

Referring to FIG. 6, carrier wafer 14 shown in FIG. 5 has been removed from silicon layer 20. In some embodiments, carrier wafer 14 is used in other semiconductor applications, which minimizes the waste of silicon. Referring to FIG. 7, a circuit package 80 is formed by using silicon layer 20 of SOI wafer 10 shown in FIG. 1. This is advantageous in some embodiments because device 80 is thinner due to the thickness 24 of silicon layer 20.

Although some embodiments of the present invention have been described in detail, it should be understood that various changes, substitutions, and alterations can be made hereto without departing from the spirit and scope of the invention as defined by the appended claims.

What is claimed is:

1. A method of manufacturing a semiconductor device, comprising:
forming a silicon-on-insulator structure comprising a carrier silicon layer, an oxide layer disposed outwardly from the carrier silicon layer, and a silicon layer disposed outwardly from the oxide layer;
forming at least one feature at least partially in the silicon layer; and
separating the carrier silicon layer from the silicon layer by chemically removing the oxide layer.

2. The method of claim 1, wherein the at least one feature does not penetrate through the silicon layer.

3. The method of claim 1, wherein forming at least one feature comprises forming a complete circuit.

4. The method of claim 1, wherein the thickness of the silicon layer is approximately 5 microns or less.

5. The method of claim 1, wherein separating the carrier silicon layer from the silicon layer comprises dissolving the oxide layer using a mixture of hydrofluoric acid and a surfactant.

6. The method of claim 1, wherein the oxide layer is a first oxide layer, and further comprising:
forming a second oxide layer disposed outwardly from the silicon layer;
forming a protective layer disposed outwardly from the second oxide layer, and wherein separating the carrier silicon layer from the silicon layer comprises separating the carrier silicon layer from the silicon layer after forming the protective layer using a mixture of hydrofluoric acid and a surfactant.

7. The method of claim 6, wherein the protective layer overlies substantially the entire silicon layer.

8. The method of claim 1, wherein separating the carrier silicon layer from the silicon layer comprises rotating the silicon-on-insulator structure and exposing the oxide layer to a chemical.

9. A method of manufacturing a semiconductor device, comprising:
forming a silicon layer having a thickness of approximately 10 microns or less disposed outwardly from a platform;
forming at least one circuit feature at least partially in the silicon layer, wherein the at least one feature does not reach the platform; and
removing the platform after forming the feature.

10. The method of claim 9, wherein the at least one feature does not penetrate through the silicon layer.

11. The method of claim 9, wherein the thickness of the silicon layer is approximately five microns or less.

12. The method of claim 9, wherein the thickness of the silicon layer is approximately one micron or less.

13. The method of claim 9, wherein forming a silicon layer comprises forming a silicon-on-insulator wafer having a carrier silicon layer, an oxide layer disposed outwardly from the carrier silicon layer, and the silicon layer disposed outwardly from the oxide layer, wherein the oxide layer is the platform.

14. The method of claim 13, wherein removing the platform comprises at least partially dissolving the oxide layer using a mixture of hydrofluoric acid and a surfactant, and separating the carrier silicon layer from the silicon layer.

15. The method of claim 14, and further comprising forming a protective layer disposed outwardly from the at least one feature, and wherein at least partially dissolving the oxide layer comprises at least partially dissolving the oxide layer after forming the protective layer using a mixture of hydrofluoric acid and a surfactant,

16. The method of claim 15, wherein the oxide layer comprises a thickness of approximately 2 microns or less and the mixture comprises at least five percent concentration of hydrofluoric acid, and the surfactant comprises alcohol.

17. The method of claim 15, wherein the protective layer is a passivation oxide layer formed from amorphous hydrogenated silicon carbide and overlies substantially the entire silicon layer.

18. The method of claim 15, wherein the protective layer is a passivation oxide layer formed from amorphous hydrogenated boron carbide and overlies substantially the entire silicon layer.

19. The method of claim 9, wherein forming a silicon layer comprises forming a silicon-on-insulator wafer having a carrier silicon layer, a oxide layer disposed outwardly from the carrier silicon layer, and the silicon layer disposed outwardly from the oxide layer, wherein the oxide layer is the platform and wherein the thickness of the silicon layer is equal to or greater than one micron.

20. The method of claim 9, wherein the silicon layer is coupled to the platform through an oxide layer, and wherein removing the platform comprises chemically dissolving the oxide layer by rotating the silicon layer, the platform, and the oxide layer while exposing the oxide layer to a chemical.

21. The method of claim 9, wherein forming at least one circuit feature comprises forming a complete circuit.

22. A method of manufacturing a semiconductor device, comprising:
forming a silicon-on-insulator wafer comprising a carrier silicon layer, an oxide layer disposed outwardly from the carrier silicon layer, and a silicon layer disposed outwardly from the oxide layer, the oxide layer having a first thickness of approximately two microns or less and the silicon layer having a second thickness of approximately 20 microns or less;
forming at least one feature at least partially in the silicon layer;
forming a dielectric layer disposed outwardly from the silicon layer after forming the feature;
forming a passivation oxide layer disposed outwardly from the dielectric layer and substantially covering the entire dielectric layer;
coupling the passivation oxide layer to a wafer handler; and
separating the carrier silicon layer from the silicon layer by rotating the wafer handler and exposing the oxide layer to a mixture of hydrofluoric acid and a surfactant, wherein the mixture comprises at least five percent concentration of hydrofluoric acid, and wherein the surfactant comprises alcohol;

23. The method of claim 22, wherein the second thickness is approximately 10 microns or less.

24. The method of claim 22, wherein the second thickness is in a range between 1-20 microns.
